(19) United States
(12) Patent Application Publication
(10) Pub. No.: US 2015/0380635 A1
(43) Pub. Date: Dec. 31, 2015

(54) METHODS TO IMPROVE THE CRYSTALLINITY OF PbZrTiO3 AND Pt FILMS FOR MEMS APPLICATIONS

(71) Applicant: Texas Instruments Incorporated, Dallas, TX (US)

(72) Inventors: Bhaskar Srinivasan, Allen, TX (US); Sarah Emily Treece, Dallas, TX (US); YungShan Chang, Plano, TX (US); Ollen Harvey Mullis, Mansfield, TX (US); Mary Alyssa Drummond Roby, Plano, TX (US)

(73) Assignee: Texas Instruments Incorporated, Dallas, TX (US)

(21) Appl. No.: 14/734,048

(22) Filed: Jun. 9, 2015

Related U.S. Application Data
(60) Provisional application No. 62/018,776, filed on Jun. 30, 2014.

(51) Int. Cl. H01L 41/08; H01L 41/319; C23C 14/06; C23C 14/35; C23C 14/34; C23C 14/18; H01L 41/18; C23C 14/02

(52) U.S. Cl. CPC H01L 41/0815; H01L 41/18; H01L 41/319; C23C 14/025; C23C 14/027; C23C 14/35; C23C 14/34; C23C 14/185; C23C 14/06

(57) ABSTRACT

A microelectronic device containing a piezoelectric component is formed sputtering an adhesion layer of titanium on a substrate by an ionized metal plasma (IMP) process. The adhesion layer is oxidized so that at least a portion of the titanium is converted to a layer of substantially stoichiometric titanium dioxide (TiO₂) at a top surface of the adhesion layer. A layer of platinum is formed on the titanium dioxide of the adhesion layer; the layer of platinum has a (111) crystal orientation and an X-ray rocking curve FWHM value of less than 3 degrees. A layer of piezoelectric material is formed on the layer of platinum. The piezoelectric material may include lead zirconium titanate.

### CROSS-REFERENCE TO RELATED APPLICATIONS

This application claims the benefit of priority under U.S.C. §119(e) of U.S. Provisional Application 62/018,776 (Texas Instruments docket number TI-74772PS), filed Jun. 30, 2014, which is hereby incorporated by reference in its entirety.

### FIELD OF THE INVENTION

This invention relates to the field of microelectronic devices with piezoelectric components. More particularly, this invention relates to thin films in microelectronic devices with piezoelectric components.

### BACKGROUND OF THE INVENTION

Some microelectronic devices contain piezoelectric components with lead zirconium titanate (PZT) piezoelectric layers and platinum contact layers. It is desirable to have a high degree of crystallinity in the platinum contact layers on which the PZT layers are formed. A high degree of crystallinity would produce an X-ray rocking curve full width at half maximum (FWHM) value of less than 3 degrees. Forming the platinum contact layers to have the desired high degree of crystallinity has been problematic, and X-ray rocking curve FWHM values greater than 5 degrees are common, resulting in pyrochlore phase regions in the PZT layers and thus less than desired performance in the piezoelectric component.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

A microelectronic device containing a piezoelectric component is formed by providing a substrate, and forming an adhesion layer of titanium on the substrate by an ionized metal plasma (IMP) process. The adhesion layer is oxidized so that at least a portion of the titanium is converted to a layer of substantially stoichiometric titanium dioxide (TiO₂) at a top surface of the adhesion layer. A layer of platinum is formed on the titanium dioxide of the adhesion layer; the layer of platinum has an X-ray rocking curve FWHM value of less than 3 degrees. A layer of piezoelectric material is formed on the layer of platinum.

### DESCRIPTION OF THE VIEWS OF THE DRAWING

FIG. 1A through FIG. 1D are cross sections of an example microelectronic device containing a piezoelectric component, depicted in successive stages of an example method of fabrication.

FIG. 2 is a chart of an X-ray rocking curve for a platinum layer formed as described in reference to FIG. 1A through FIG. 1C.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

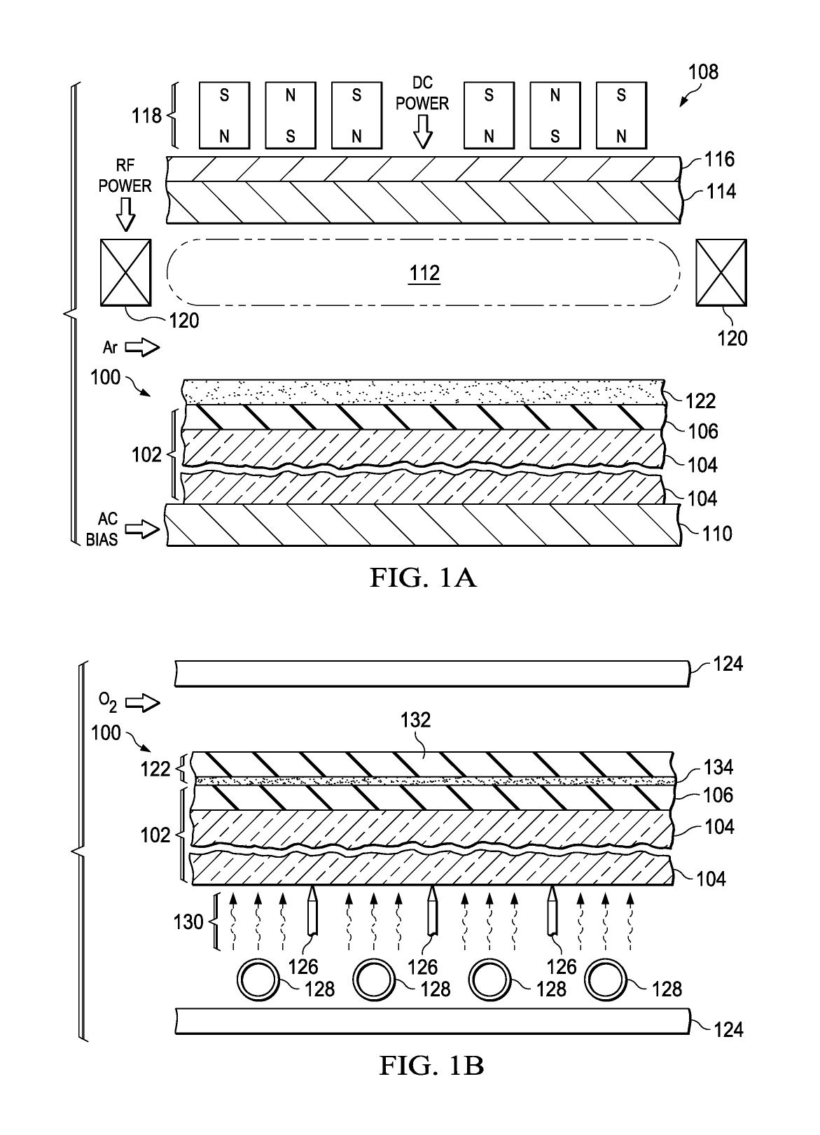

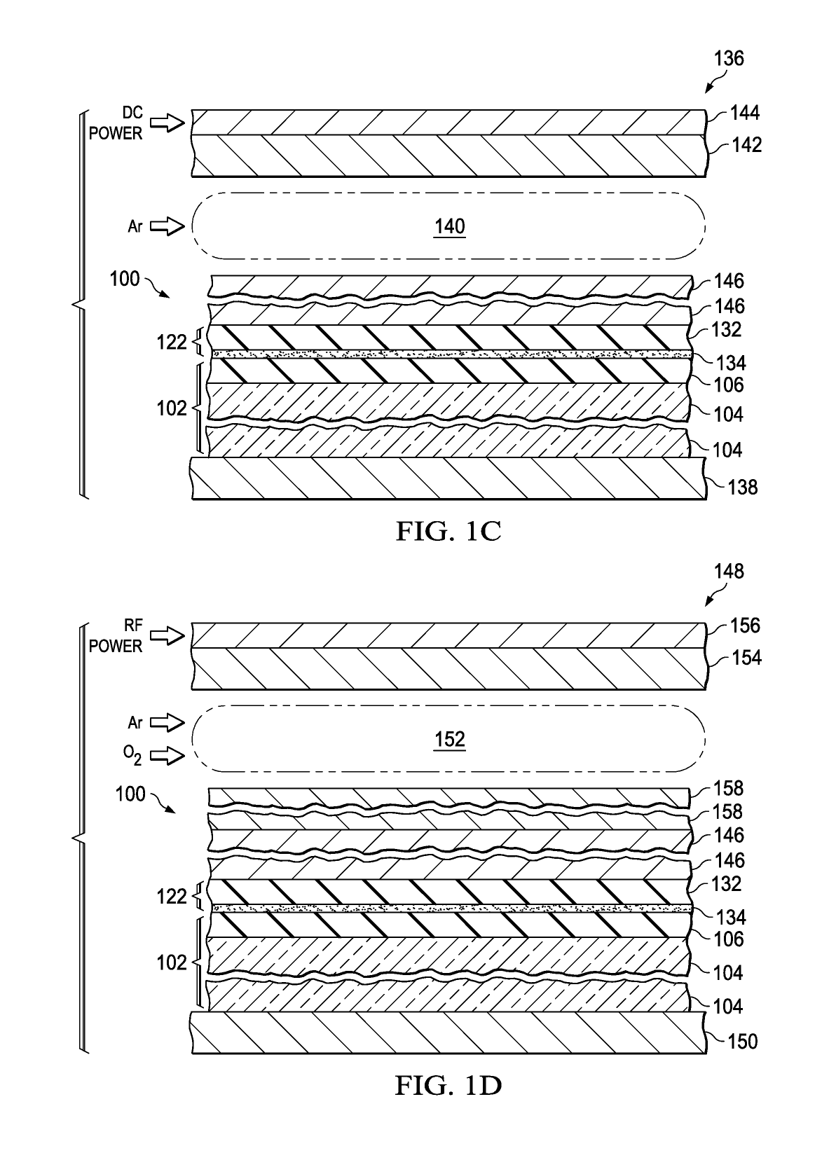

FIG. 1A through FIG. 1D are cross sections of an example microelectronic device containing a piezoelectric component, depicted in successive stages of an example method of fabrication. Referring to FIG. 1A, the microelectronic device 100 is formed on a substrate 102 which may be a semiconductor wafer such as a silicon wafer, an insulating material such as glass, sapphire, plastic, ceramic, or other material. The substrate 102 includes a piezoelectric base 104 which may be a solid base, or may be a beam or cantilever. The substrate 102 may include a dielectric layer 106 disposed on the structural base 104. The dielectric layer 106 may include one or more layers of silicon dioxide-based material such as silicon dioxide formed by a plasma enhanced chemical vapor deposition (PECVD) process using tetraethyl orthosilicate (TEOS), boron phosphorus silicate glass, and/or organic silicate glass (OSG), and/or other dielectric material such as silicon nitride or aluminum oxide.

An adhesion layer 122 of titanium is formed using an IMP process on the substrate 102, on the dielectric layer 106 if present. In an example IMP process, the substrate 102 is placed in an IMP chamber 108. The substrate 102 is disposed on a chuck 110 which is maintained at an operating temperature of about 200° C. The IMP chamber 108 includes a region for a plasma 112 over the substrate 102 and a titanium target 114 disposed over the plasma region 112. The IMP chamber 108 further includes a top electrode 116 disposed over, and electrically coupled to, the titanium target 114. In the instant example, focusing magnets 118 are disposed over the top electrode 116. A radio frequency (RF) coil 120 is disposed around the plasma region 112. In the instant example, process parameters will be recited for a case in which the substrate 102 is a 200 millimeter diameter substrate. Argon gas, designated in FIG. 1A as Ar, is flowed into the IMP chamber 108, for example at 50 standard cubic centimeters per minute (sccm) to 70 sccm. A pressure in the IMP chamber 108 is maintained at 15 millitorr to 25 millitorr. RF power is applied to the RF coil 120 at 2500 watts to 3000 watts, which is about 8.0 watts per square centimeter of substrate area (watts/cm²) to 9.5 watts/cm², to form a plasma of the argon gas in the plasma region 112, producing argon ions. Direct current (DC) power, designated in FIG. 1A as DC POWER, is applied to the top electrode 116 at 1500 watts to 1750 watts, which is about 4.8 watts/cm² to 5.6 watts/cm², to attract argon ions from the plasma region 112 to the titanium target 114, which sputter titanium atoms from the titanium target 114. The magnets 118 focus the argon ions to increase a rate of producing the sputtered titanium atoms. The sputtered titanium atoms are ionized in the plasma region 112. Alternating current (AC) bias power, designated in FIG. 1A as AC BIAS, is applied to the chuck 110 at 150 watts to 250 watts, which is about 0.48 watts/cm² to 0.64 watts/cm², to provide a voltage bias between the plasma in the plasma region 112 and the substrate 102 so as to attract the ionized titanium atoms to the substrate 102 to form the adhesion layer 122 of titanium on the substrate 102, on the dielectric layer 106 if present. The voltage bias provided by the AC power may advantageously improve uniformity and density of the adhesion layer 122 of titanium. The adhesion layer 122 is at least 10 nanometers thick, and may be, for example, 15 nanometers to 30 nanometers thick. Other IMP processes for forming the adhesion layer 122 are within the scope of the instant example. In one version of the instant example, the magnets 118 may be omitted.

Referring to FIG. 1B, a layer of titanium dioxide 132 at least 10 nanometers thick is formed at a top surface of the adhesion layer 122. In an example process for forming the layer of titanium dioxide 132, the microelectronic device 100 is placed in a rapid thermal processor (RTP) chamber 124. The substrate 102 may be supported at a bottom surface by pins 126 so as to thermally isolate the microelectronic device 100. An oxidizing gas such as oxygen, designated in FIG. 1B as O₂, is flowed into the RTP chamber 124. The microelectronic device 100 is heated to a temperature of 650° C. to 750° C., for example by radiant heating elements 128 below the substrate 102 which provide radiant energy 130 to the substrate 102. The substrate 102 may be heated to about 650° C. to about 750° C. for an oxidation time of, for example, 45 seconds to 90 seconds. The oxidizing gas reacts with the titanium in the adhesion layer 122 to form the layer of titanium dioxide 132. The layer of titanium dioxide 132 may be, for example, 20 nanometers to 40 nanometers thick. The layer of titanium dioxide 132 is substantially stoichiometric, due to the uniformity and density provided by the titanium IMP process described in reference to FIG. 1A. The layer of titanium dioxide 132 may further have fewer non-uniformity defects due to the uniformity and density provided by the titanium IMP process. There may be a residual layer of titanium 134 under the layer of titanium dioxide 132 after the layer of titanium dioxide 132 is formed. Other methods of forming the layer of titanium dioxide 132, such as a furnace oxidation process, are within the scope of the instant example.

Referring to FIG. 1C, a layer of platinum 146 with a 111 crystal orientation is formed. In an example process for forming the layer of platinum 146, the microelectronic device 100 is placed in a sputter chamber 136. The substrate 102 is disposed on a chuck 138 which is maintained at an operating temperature of about 400° C. The sputter chamber 136 includes a region for a plasma 140 over the substrate 102 and a platinum target 142 disposed over the plasma region 140. The sputter chamber 136 further includes a top electrode 144 disposed over, and electrically coupled to, the platinum target 142. Argon gas, designated in FIG. 1C as Ar, is flowed into the sputter chamber 136. DC power, designated in FIG. 1C as DC POWER, is applied to the top electrode 144 to form a plasma of the argon gas in the plasma region 140, producing argon ions. The argon ions sputter platinum atoms from the platinum target 142 onto the layer of titanium dioxide 132 to form the layer of platinum 146 with a 111 crystal orientation. The layer of platinum 146 may be, for example, 75 nanometers to 150 nanometers thick. Due to the layer of titanium dioxide 132 being substantially stoichiometric, the layer of platinum 146 has a high degree of crystallinity, with an X-ray rocking curve FWHM value of less than 3 degrees. Forming the layer of platinum 146 at about 400° C. may advantageously improve the degree of crystallinity compared to a lower temperature.

Referring to FIG. 1D, a layer of piezoelectric material 158 is formed on the layer of platinum 146. The layer of piezoelectric material 158 may comprise lead zirconium titanate. In an example process for forming the layer of piezoelectric material 158, the microelectronic device 100 is placed in a sputter chamber 148. The substrate 102 is disposed on a chuck 150 which is maintained at an operating temperature of about 375° C. to 425° C. The sputter chamber 148 includes a region for a plasma 152 over the substrate 102 and a lead zirconium titanium target 154 disposed over the plasma region 152. The sputter chamber 148 further includes a top electrode 156 disposed over, and electrically coupled to, the lead zirconium titanium target 154. Argon gas, designated in FIG. 1D as Ar, and oxygen gas, depicted in FIG. 1D as O₂, are flowed into the sputter chamber 148. RF power, designated in FIG. 1D as RF POWER, is applied to the top electrode 156 to form a plasma of the argon and oxygen gases in the plasma region 152, producing argon ions and oxygen radicals. The argon ions sputter lead, zirconium and titanium atoms from the lead zirconium titanium target 154 onto the layer of platinum 146 to form the layer of piezoelectric material 158, comprising lead zirconium titanate. The layer of piezoelectric material 158 may be, for example, 1.5 microns to 3 microns thick. Due to the layer of platinum 146 having a high degree of crystallinity, the layer of piezoelectric material 158 may advantageously have substantially all perovskite crystal structure and substantially no pyrochlore phase.

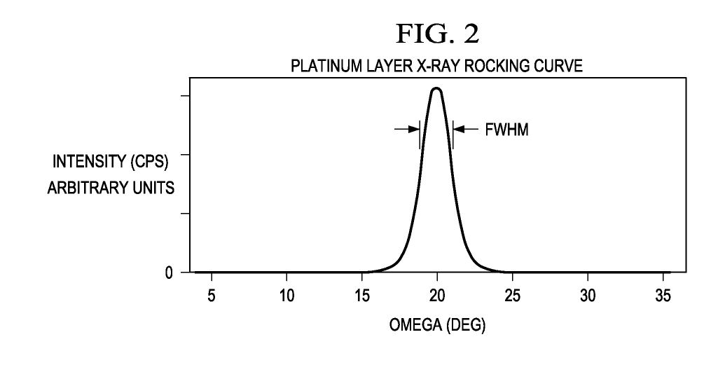

FIG. 2 is a chart of an X-ray rocking curve for a platinum layer formed as described in reference to FIG. 1A through FIG. 1C. The data shown in FIG. 2 was acquired during activities in pursuit of the instant invention. The horizontal axis of the X-ray rocking curve has units of degrees of angle, designated as OMEGA in FIG. 2. The vertical axis of the X-ray rocking curve has units of count per second, designated as Intensity (cps) in FIG. 2. The FWHM value is defined as the width of the X-ray rocking curve at a height of half of the maximum value. The X-ray rocking curve of FIG. 2 has a FWHM value significantly less than 3 degrees. Microelectronic devices built in pursuit of the instant invention in which the substrate was heated to about 650° C. during formation of the titanium dioxide produced platinum X-ray rocking curve FWHM values of less than 3.0 degrees. Heating to about 650° C. may advantageously reduce degradation of components in the microelectronic device while providing desired performance by the piezoelectric layer. Other microelectronic devices built in pursuit of the instant invention in which the substrate was heated to about 750° C. during formation of the titanium dioxide produced platinum X-ray rocking curve FWHM values of less than 2.3 degrees. Heating to about 750° C. may advantageously provide more performance by the piezoelectric layer. Further microelectronic devices built in pursuit of the instant invention in which the substrate was heated to about 700° C. during formation of the titanium dioxide produced platinum X-ray rocking curve FWHM values of less than 2.5 degrees. Heating to about 700° C. may advantageously provide a desired tradeoff between degradation of components and piezoelectric performance.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method of forming a microelectronic device containing a piezoelectric component, comprising the steps:
providing a substrate;
forming an adhesion layer of titanium at least 10 nanometers thick over the substrate by an ionized metal plasma (IMP) process;
exposing the adhesion layer to an oxidizing ambient to form a layer of titanium dioxide at least 10 nanometers thick, the titanium dioxide being substantially stoichiometric;
forming a layer of platinum on the layer of titanium dioxide, the platinum having a crystal orientation of (111) and having an X-ray rocking curve full width at half maximum (FWHM) value of less than 3 degrees; and
forming a layer of piezoelectric material on the layer of platinum.

2. The method of claim 1, wherein the IMP process uses magnets above a titanium target.

3. The method of claim 1, wherein the IMP process applies alternating current (AC) power at about 0.48 watts per square centimeter of substrate area (watts/cm²) to 0.64 watts/cm² to a chuck under the substrate to provide a voltage bias between the substrate and a plasma above the substrate.

4. The method of claim 1, wherein the titanium in the adhesion layer is 15 nanometers to 30 nanometers thick after the IMP process is completed, before exposing the adhesion layer to the oxidizing ambient.

5. The method of claim 1, wherein the titanium dioxide is 20 nanometers to 40 nanometers thick.

6. The method of claim 1, wherein the substrate is heated to about 650° C. to about 750° C. while the adhesion layer is exposed to the oxidizing ambient.

7. The method of claim 1, wherein the substrate is heated to about 750° C. while the adhesion layer is exposed to the oxidizing ambient, and wherein the layer of platinum has an X-ray rocking curve FWHM value of less than 2.3 degrees.

8. The method of claim 1, wherein the layer of platinum is 75 nanometers to 150 nanometers thick.

9. The method of claim 1, wherein the layer of platinum is formed by a sputter process.

10. The method of claim 1, wherein the substrate is heated to about 400° C. while the layer of platinum is formed.

11. The method of claim 1, wherein the layer of piezoelectric material comprises lead zirconium titanate.

12. The method of claim 1, wherein layer of piezoelectric material is formed by a sputter process.

13. The method of claim 1, wherein layer of piezoelectric material has substantially all perovskite crystal structure.

14. A microelectronic device containing a piezoelectric component, comprising:
a substrate;
an adhesion layer disposed over the substrate, the adhesion layer comprising a layer of titanium dioxide at least 10 nanometers thick, the titanium dioxide being substantially stoichiometric;
a layer of platinum disposed on the layer of titanium dioxide, the platinum having a crystal orientation of (111) and having an X-ray rocking curve FWHM value of less than 3 degrees; and
a layer of piezoelectric material disposed on the layer of platinum.

15. The microelectronic device of claim 14, wherein the substrate comprises a dielectric layer disposed under, and in contact with, the adhesion layer.

16. The microelectronic device of claim 14, wherein the layer of titanium dioxide is 20 nanometers to 40 nanometers thick, and the adhesion layer comprises a layer of titanium under the layer of titanium dioxide.

17. The microelectronic device of claim 14, wherein the layer of platinum has an X-ray rocking curve FWHM value of less than 2.3 degrees.

18. The microelectronic device of claim 14, wherein the layer of platinum is 75 nanometers to 150 nanometers thick.

19. The microelectronic device of claim 14, wherein the layer of piezoelectric material comprises lead zirconium titanate.

20. The microelectronic device of claim 14, wherein the layer of piezoelectric material has substantially all perovskite crystal structure.

21. A method of forming a microelectronic device containing a piezoelectric component, comprising the steps:
providing a substrate;
forming an adhesion layer of titanium over the substrate by an IMP process;
exposing the adhesion layer to an oxidizing ambient to form a layer of titanium dioxide, the titanium dioxide being substantially stoichiometric;
forming a layer of platinum on the layer of titanium dioxide; and
forming a layer of piezoelectric material on the layer of platinum.

22. A method of forming a microelectronic device containing a piezoelectric component, comprising the steps:
providing a substrate;
forming an adhesion layer of titanium at least 10 nanometers thick over the substrate by an IMP process;
exposing the adhesion layer to an oxidizing ambient to form a layer of titanium dioxide at least 10 nanometers thick, the titanium dioxide being substantially stoichiometric;
forming a layer of platinum on the layer of titanium dioxide, the platinum having a crystal orientation of (111) and having an X-ray rocking curve FWHM value of less than 3 degrees; and
forming a layer of lead zirconium titanate on the layer of platinum.
